(19) United States
(12) Patent Application Publication
(10) Pub. No.: US 2007/0072334 A1
(43) Pub. Date: Mar. 29, 2007

(54) Semiconductor fabrication process employing spacer defined vias

(75) Inventors: Marius K. Orlowski, Austin, TX (US); Kathleen C. Yu, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(73) Assignee: Freescale Semiconductor, Inc.

(21) Appl. No.: 11/239,282

(22) Filed: Sep. 29, 2005

(51) Int. Cl. H01L 21/00; H01L 21/8236

(52) U.S. Cl. 438/95; 438/276; 438/278

(57) ABSTRACT

A semiconductor fabrication process includes forming a first etch mask (131) that defines a first opening (132) and a second etch mask (140) that defines a second opening (142) overlying an interlevel dielectric (ILD) (108). The ILD (108) is etched to form a first via (154) defined by the first opening (132) and a second via (152) defined by the second opening (142). The first etch mask (131) may include a patterned hard mask layer (122) and the second etch mask may be a patterned photoresist layer (140). The first etch mask may further include spacers (130) adjacent sidewalls of the patterned hard mask layer (122). The patterned hard mask layer (122) may be a titanium nitride and the spacers (130) may be silicon nitride. The ILD (108) may be an CVD low-k dielectric layer overlying a CVD low-k etch stop layer (ESL) (106).

### FIELD OF THE INVENTION

The invention is in the field of semiconductor fabrication processes and, more particularly, backend processing including the formation of interconnect layers and vias between the layers.

### RELATED ART

In the field of semiconductor fabrication processing, backend processing (i.e., the formation of interconnect layers and the vias or contacts that connect the interconnect layers to each other and to the transistors and other devices on the wafer) can be extremely challenging. In particular, resolving the critical dimensions of a particular process using photolithography equipment is always difficult. This is especially true for very small features such as the vias that form links between different interconnect layers. Resolving minimum dimension vias is a difficult challenge for photolithography equipment because of various photolithography effects such as notching caused by reflected light or optical proximity effects. Some of these effects may be affected by the density of features in a particular area. If the density of features varies significantly, photolithography processing optimized for dense areas of the device may exhibit undesirable effects where features are sparse and vice versa. With respect to vias, for example, it is difficult to optimize the photolithography process for vias when the density of vias varies across a device. It would be desirable to implement a backend processing sequence that facilitates the definition and resolution of vias and other backend features while alleviating the demands placed on the photolithography equipment.

### BRIEF DESCRIPTION OF THE DRAWINGS

The present invention is illustrated by way of example and not limited by the accompanying figures, in which like references indicate similar elements, and in which:

FIG. 1 is a partial cross sectional view of a wafer at an immediate stage in the fabrication of an integrated circuit illustrating a patterned photoresist layer over a hard mask layer;

FIG. 2 depicts processing subsequent to FIG. 1 in which the hard mask layer is patterned;

FIG. 3 depicts processing subsequent to FIG. 2 in which spacers are formed on sidewalls of the hard mask layer;

FIG. 4 depicts processing subsequent to FIG. 3 in which a photoresist layer is patterned overlying the hard mask layer and the spacers;

FIG. 5 depicts processing subsequent to FIG. 4 in which vias are etched through an interlevel dielectric layer emphasizing photoresist-defined vias in dense regions and a spacer defined via in an isolated region;

FIG. 6 depicts processing subsequent to FIG. 5 in which the patterned photoresist layer and the spacers are removed to define trench openings;

FIG. 7 depicts processing subsequent to FIG. 6 in which the vias are filled with photoresist;

FIG. 8 depicts processing subsequent to FIG. 7 in which photoresist plugs are formed in the vias;

FIG. 9 depicts processing subsequent to FIG. 8 in which trenches are formed;

FIG. 10 depicts processing subsequent to FIG. 9 in which the photoresist plugs are removed;

FIG. 11 depicts processing subsequent to FIG. 10 the trenches and plugs are filled and polished back to form an interconnect;

FIG. 12 is a top view of the wafer of FIG. 5 illustrating a via that is defined by spacers on two sides and a via that is defines by spacers on three sides; and

FIG. 13 is a top view of the wafer of FIG. 5 illustrating a via that is defined by spacers on all sides.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE DRAWINGS

Disclosed is a fabrication process that, in one embodiment, combines photolithographically defined features and spacer defined features (spacers) on sidewalls of existing features such as the sidewalls of a hard mask layer. In an embodiment emphasizing the creation of backend vias, vias in densely populated regions of a device are defined by photoresist (i.e., photolithographically) while isolated vias are defined by spacers. This processing alleviates the resolution requirements for isolated vias, which is a significant benefit for backend processing. In another embodiment, a design tool analysis application enables mask preparation software to define via dimensions based on the position and size of the spacers.

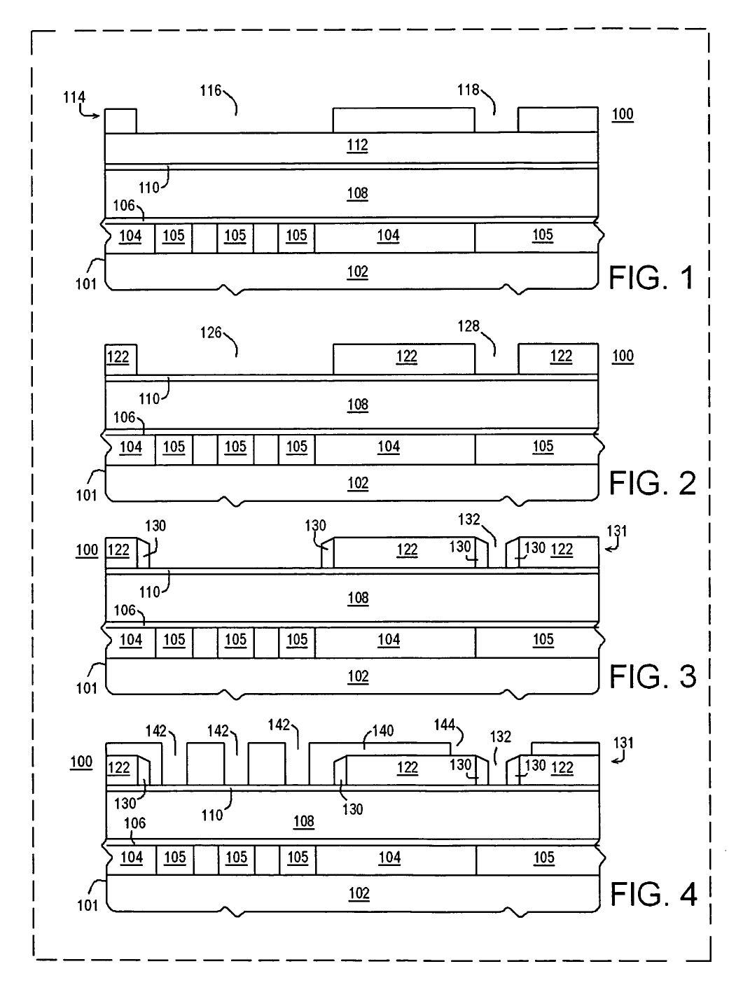

Turning now to the drawings, FIG. 1 is a partial cross sectional view of a wafer 101 at an intermediate stage in the fabrication of an integrated circuit 100 according to one embodiment. In the depicted embodiment, wafer 101 includes a layer of interconnects 105 (also referred to collectively as interconnect layer 105) embedded in an interlevel dielectric layer (ILD) 104 overlying a substrate 102. In addition to including a physical substrate of wafer 101, substrate 102 may include all active devices fabricated in or on the substrate and all interconnect layers fabricated prior to interconnect layer 105.

In one embodiment, interconnects 105 are copper or copper alloy. In other embodiments, other conductive materials such as Al, W, Ni, Ag and alloys thereof may be used. In some embodiments, a barrier layer (not depicted) is present between interconnect 105 and ILD 104. ILD 104 is preferably a low-k dielectric (i.e., a dielectric having a dielectric constant that is less than the dielectric constant of silicon dioxide, <4.0). An etch stop layer (ESL) 106 covers interlevel dielectric 104 and interconnects 105. ESL layer 106, in addition to providing a stopping layer that facilitates end point determination when etching through the a second low-k ILD 108 formed above ESL 106, also provides a barrier layer that prevents or limits migration from interconnects 105, especially in a copper embodiment of interconnects 105. ESL layer 106 is preferably a low-k dielectric material such as CVD silicon carbide, which may or may not include nitrogen. Other low-k ESL layers may include inorganic, organic or inorganic/organic hybrid spin-on or CVD layers in addition to self aligned barriers. Although silicon nitride is suitable for use as an ESL and a barrier layer, the relatively high dielectric constant of silicon nitride generally makes it undesirable in a low-k backend application. Although FIG. 1 depicts ESL 106 as a blanket layer that is non-selectively formed over ILD 104 and interconnects 105, another embodiment may pattern ESL 106 before depositing or otherwise forming ILD 108. In a patterned ESL embodiment, the ESL 106 would be patterned so that the remaining portions of the ESL overlie the interconnects 105. In other embodiments, selective patterning of ESL 106 may include selective deposition techniques including constituent materials such as Co, W, Ta, TaN, Ru, CuSiN, Ni, Mo, or zeolite materials.

FIG. 1 depicts second low-k ILD 108 formed over ESL layer 106. Second low-k ILD 108 may be of the same material as low-k ILD 104. In one embodiment, low-k ILDs 104 and 108 include an organic spin-on low-k material such as the SiLK® product from Dow Chemical. In other embodiments, low-k ILDs 104 and 108 may include an inorganic spin on material such as a nano-clustering silica material from CCIC, Ltd, a hybrid spin-on, or a CVD low-k material such as the Black Diamond™ family of products from Applied Materials, or sacrificial airgap layer materials. It is recognized that a hybrid ILD structure may be formed with different combinations of low-k materials and non low-k materials (e.g., F-TEOS, oxide or TEOS) or low-k materials at the via and trench layers. It is also recognized that an intermediate ESL layer may be used between the metal and via layer.

FIG. 1 also depicts a first sacrificial hard mask layer 110 overlying second low-k ILD 108 and a second sacrificial hard mask layer 112 overlying the first sacrificial hard mask layer 110. In one embodiment, first sacrificial hard mask layer 110 is a TEOS (tetraethylorthosilicate) or other silicon-oxide layer. In this embodiment, the second sacrificial hard mask layer 112 preferably exhibits good etch selectivity with respect to the first sacrificial hard mask layer 110 and low-k dielectric 108. Materials suitable for use as second sacrificial hard mask layer 112 include titanium nitride, which can be sputter deposited and silicon nitride which can be deposited by CVD. It is recognized that additional hard mask layers (dual, triple, etc) may be used with various combination of inorganic, organic or metallic layers for etch selectivity. A patterned masking layer 114 has been formed on second sacrificial hard mask layer 112. Patterned masking layer 114 is preferably patterned photoresist. Patterned masking layer 114 defines a relatively wide opening 116 and a relatively narrow opening 118.

In FIG. 2, the second sacrificial hard mask layer 112 of FIG. 1 has been patterned to form patterned hard mask layer 122 overlying first sacrificial hard mask layer 110. Patterned hard mask layer 122 includes first and second openings 126 and 128 corresponding to openings 116 and 118 (of FIG. 1). Patterned masking layer 114 is then stripped or otherwise removed from wafer 101. In an embodiment of the invention that uses photolithography to define at least some interconnect vias and spacers to define at least some other vias, opening 126 may be associated with the photolithography defined vias and opening 128 may be associated with the spacer defined vias as will be discussed in greater detail in the following paragraphs.

Referring now to FIG. 3, an etch mask 131 is created by forming spacers 130 on sidewalls of patterned mask layer 122. For an implementation in which patterned mask layer 122 is titanium nitride, spacers 130 are preferably of a material that exhibits good etch selectivity with respect to patterned hard mask layer 122 and first sacrificial hard mask layer 110. An exemplary material in this embodiment is silicon nitride spacers coupled with a patterned TiN mask layer. Spacers 130 may be formed by conventional means in which a conformal layer of the spacer material is deposited non-selectively over wafer 101 and anisotropically etched as will be familiar to those in the field of semiconductor fabrication. In other embodiments, it is recognized that patterned mask layer 122 may include alternate materials such as Al₂O₃, TaN, etc.

In the depicted embodiment, the formation of spacers 130 on the sidewalls of opening 128 produces a narrow opening 132 that will be used to define an isolated via. The spacers on sidewalls of opening 126, in contrast, will not be used to define the boundaries of via structures. Instead, as depicted in FIG. 4, a patterned photoresist layer 140 is formed that defines densely spaced openings 142. Thus, wafer 101 as depicted in FIG. 4 includes a first etch mask 131 (FIG. 3) that includes patterned hard mask 122 and spacers 130 and another etch mask in the form of patterned photoresist layer 140.

In the depicted embodiment, patterned photoresist layer 140 defines openings 142 that are aligned with, but smaller than, opening 126 of patterned hard mask 122 (see FIG. 2). Patterned photoresist layer 140 also defines an isolated opening 144 that is aligned with, but wider than opening 132 defined by first etch mask 131. In this configuration, features that will be subsequently etched into the underlying dielectric layer 108 are defined by patterned photoresist mask 140 in one region of wafer 101 and by first etch mask 131 in another region of wafer 101.

Those familiar with photolithographic processing will recognize that optimizing the parameters for exposing photoresist layer 140 is difficult because parameters that may be optimized with respect to features formed in densely populated regions may be sub-optimal with respect to isolated features. The processing depicted in FIG. 4 addresses this problem by using photolithographically-defined elements (e.g., openings 142) to define features (e.g., vias) in a first region of integrated circuit 100 and by using spacer-defined elements (e.g., opening 132) to define features in a second region of the integrated circuit.

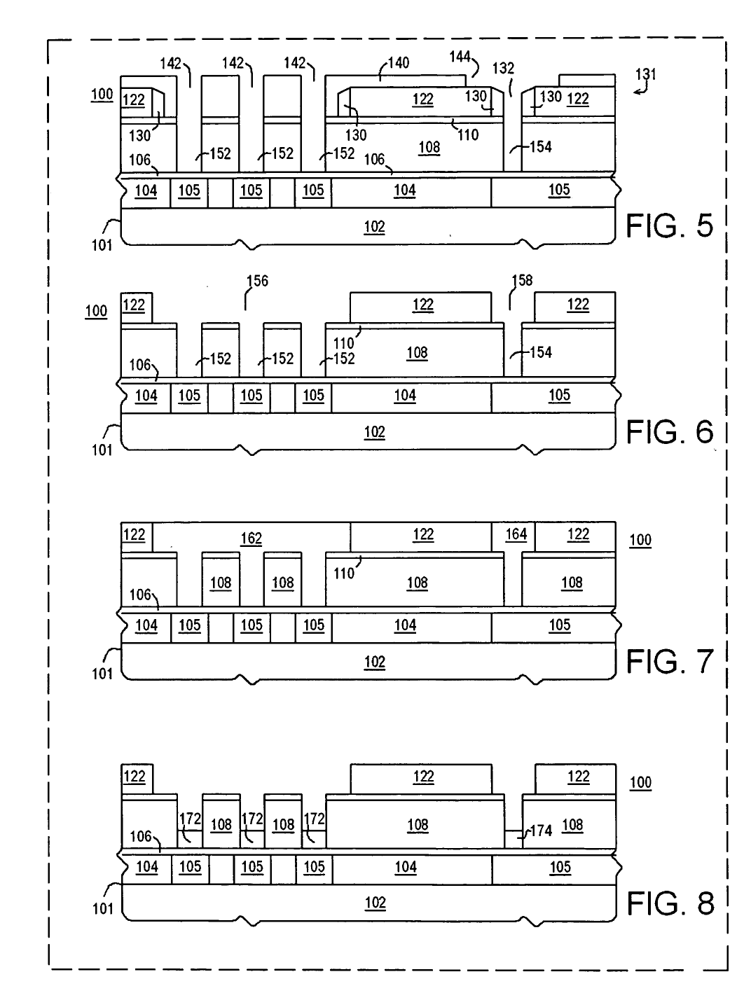

Referring now to FIG. 5, a via etch is performed by etching through first sacrificial hard mask layer 110 and low-k ILD 108 using patterned photoresist layer 140 and etch mask 131 as etch masks. In the depicted embodiment, the via etch is terminated after etching through first sacrificial hard mask layer 110 and ILD layer 108, but before etching through ESL 106. In other embodiments, the via etch of FIG. 5 may etch through ESL layer 106 all the way to interconnects 105.

The via etch of FIG. 5 results in the formation of photolithographically-defined vias 152 and a spacer-defined via 154. In the depicted implementation, spacer-defined via 154 is characterized as an isolated via. The definition of an isolated via is implementation dependent, but, in one embodiment, an isolated via is defined as a via that is at displaced by at least 5 CD from the closest neighboring via where CD represents the minimum dimension for vias.

Referring to FIG. 12 and FIG. 13, a top view of a portion of wafer 101 as depicted in FIG. 5 is shown to illustrate various examples of spacer defined vias 154. In FIG. 12, spacer 130 is seen from the top as lining a perimeter portion of an elongated rectangular trench 210. In this embodiment, trench 210 may be suitable for defining an interconnect. For purposes of this disclosure, an interconnect refers to a conductive structure designed to convey electrical signals within a single physical layer of the integrated circuit where each interconnect layer is separated from the adjacent interconnect layers by an ILD. In contrast, a via or contact structure is designed to convey electrical signals between two (or more) layers of interconnects. Thus, an interconnect is an intralayer structure while a via is an interlayer structure. FIG. 12, depicts a via 154-2 that is defined by spacer structure 130 on two sides, namely, sides 155-1 and 155-2, and on two sides, namely sides 155-3 and 155-4, by opening 144-1 in photoresist layer 140. FIG. 12 also depicts a via 154-3 at an end of rectangular trench 120. Via 154-3 is defined on three sides by spacer structure 130 and on one side, namely, side 155-5, by opening 144-2 in photoresist layer 140. FIG. 13 depicts a via 154-4 defined on four sides by a spacer structure 130.

Following the via etch of FIG. 5, patterned photoresist layer 140 and spacers 130 are removed to define trenches 156 and 158 shown in FIG. 6. In this embodiment, the boundaries of trenches 156 and 158 are defined by patterned hard mask layer 122. In other embodiments, patterned hard mask layer 122 may be further patterned so that the trenches 156 and 158 may have different dimensions. For example, the opening 128 (FIG. 2) in patterned hard mask 122, together with the size of the spacers 130, determines the dimensions of the opening 132 (FIG. 3) and the resulting via 154. In the absence of additional processing, the opening 128 in patterned hard mask layer also determines the dimensions of trench 158. If a larger (e.g., wider) or deeper trench is desirable, patterned hard mask 122 may be further patterned, masked, and etched to alter the dimension of trench 158 relative to opening 128. Spacer removal is preferably optimized to prevent low-k damage and subsequent increase in the film dielectric constant. It is therefore recognized that spacer removal may be performed at alternate stages in the process (e.g., after patterning of first sacrificial hard mask layer 110 or during via ESL open to reduce low-k damage specific to the material used).

Referring to FIG. 7 and FIG. 8, one embodiment of the depicted processing sequence includes the formation of photoresist plugs (172, 174) in a lower portion of the vias prior to a trench etch. In this embodiment, photoresist plugs 172, 174 prevent erosion of the vias, especially at bottom corners of the vias, during the trench etch, which is typically a highly reactive etch. Other embodiments, however, may elect to forego the additional processing required to form the plugs. Plugs 172 and 174 are formed by first spin depositing photoresist structures 162 and 164 to fill vias (152, 154) and trenches (156, 158). Photoresist structures 162 and 164 are then exposed and partially etched back using known resist etch techniques.

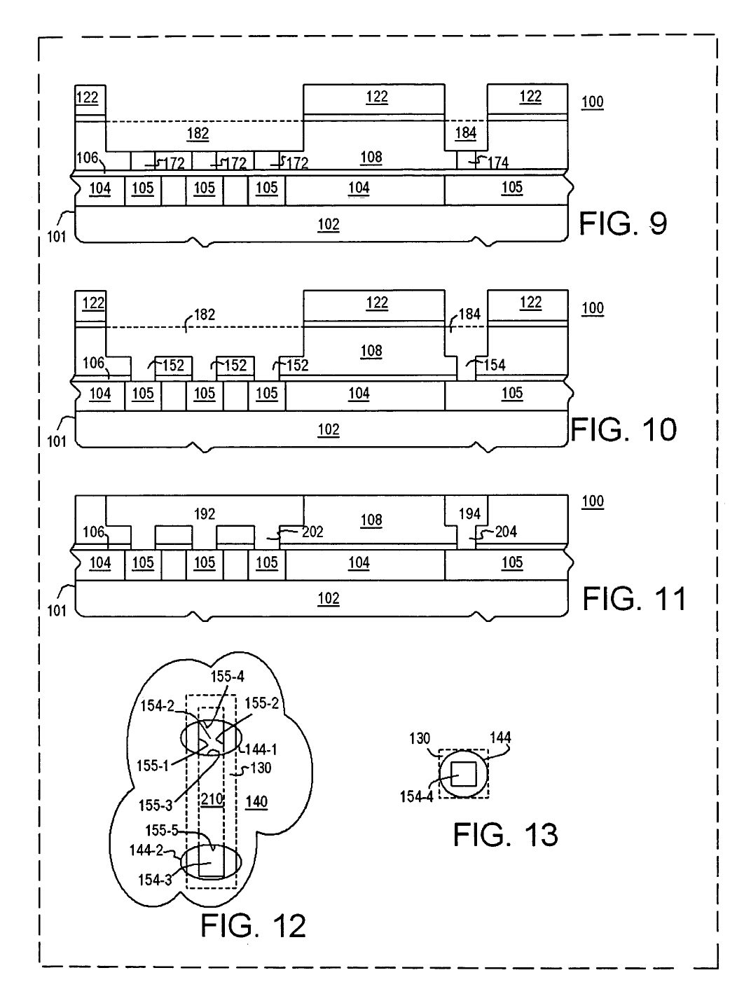

Following formation of resist plugs 172 and 174, an etch is performed as depicted in FIG. 9, to form trenches 182 and 184. In the depicted embodiment, trenches 182 and 184 extend vertically from an upper layer of ILD 108 to an upper surface of resist plugs 172 and 174. In embodiments that omit photoresist plugs 172 and 174, the etch (referred to as a trench etch) is a timed etch that is timed to etch only partially through ILD 108. The trench etch of FIG. 9 is followed, as depicted in FIG. 10, by stripping away photoresist plugs 172 and 174 and performing a short etch to clear ESL 106 at the bottom of vias 152 and 154. In other embodiments, such as selective barrier deposition, removal of the bottom layer may be excluded or may be performed during the subsequent conductive material deposition. It is understood that other embodiments exist wherein a resist plug is not used.

In FIG. 11, a conductive material such as copper is deposited and planarized to fill vias 152 and 154 and trenches 182 and 184 with interconnect structures 192 and 194. The patterned hard mask layer 122 and first sacrificial hard mask layer 110 have also been removed as depicted in FIG. 11. Removal of patterned hard mask layer 122 and first sacrificial hard mask layer 110 preferably occurs primarily before depositing and planarizing the copper or other conductive material to form interconnects 192 and 194. In one embodiment, deposition of the copper or other conductive material is preceded by forming a thin barrier layer of Ta, TaN, Co, W, Ni, Ru, TiN, a combination thereof, or another material (not depicted) on the sidewalls of vias 172 and 174 and trenches 182 and 184. Planarization of the conductive layers to form interconnect structures 192 and 194 includes a conventional chemical mechanical polish process, possibly in combination with other an etch back or other planarization techniques. In embodiments using copper for interconnects 192 and 194, an ESL layer (not depicted) may be deposited and possibly patterned or self-aligned overlying interconnects 192 and 194.

As depicted in FIG. 11, integrated circuit 100 thus includes a first interconnect 194 including a first via 204 that is defined by a spacer structure formed on a sidewall of a photolithographically patterned hard mask layer. Integrated circuit 100 also includes a second interconnect 192 having a second via 202 that is defined by a conventional photolithographic process. In the depicted embodiment, first via 204 is characterized as an isolated via that is distal from its nearest neighboring via while second via 202 is characterized as a via formed in a densely populated region of integrated circuit 100.

In the foregoing specification, the invention has been described with reference to specific embodiments. However, one of ordinary skill in the art appreciates that various modifications and changes can be made without departing from the scope of the present invention as set forth in the claims below. For example, the substrate 102 may include MOS (metal oxide semiconductor) transistors, bipolar transistors, or a combination thereof. As another example, the substrate 102 of wafer 101 may be a conventional bulk semiconductor wafer or, in other implementations, a semiconductor on insulator (SOI) wafer in which a buried oxide (BOX) layer underlies the active devices, which are formed in a semiconductor layer on top of the BOX layer. As another example with respect to the backend processing, the via etch, which is depicted as extending all the way to the ESL layer, may extend only partially through the ILD 108 in another embodiment. ESL layer 106 may also be removed during the via etch or after the trench etch. As still another example, although the depicted sequence is illustrated for the case of an interlevel via, other embodiments may employ the described processing sequence in the use of contact structures where a contact is a conductive structure that contacts an interconnect level on a first end and terminates on a transistor structure such as the gate electrode, the drain electrode, or the source electrode. As still another example, although the disclosed processing sequence is depicted for an application in which a single wafer is sufficient to form the desired circuit, other embodiments may incorporate multiple wafers in a 3D interconnection scheme or include contact pattern formation below a transistor structure (i.e., backside 3D interconnect formation). Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A semiconductor fabrication process, comprising:
forming a first etch mask overlying an interlevel dielectric layer (ILD) wherein the first etch mask defines a first opening;
forming a second etch mask overlying the ILD wherein the second etch mask defines a second opening; and
etching the ILD to form a first via having sidewalls defined at least partially by the first opening and a second via defined by the second opening.

2. The method of claim 1, wherein the first etch mask includes a patterned hard mask layer and wherein the second etch mask includes a patterned photoresist layer.

3. The method of claim 2, wherein the first etch mask further includes spacers adjacent sidewalls of the patterned hard mask layer.

4. The method of claim 3, wherein the patterned hard mask layer comprises titanium nitride and the spacers comprise silicon nitride.

5. The method of claim 3, wherein the patterned photoresist layer defines a third opening, wherein the third opening is aligned with and wider than the first opening and wherein the first etch mask defines a fourth opening aligned with and wider than the second opening.

6. The method of claim 3, wherein the ILD comprises an CVD inorganic low-k dielectric layer overlying a CVD low-k etch stop layer (ESL).

7. The method of claim 3, wherein portions of the sidewalls of the first via are defined by the patterned hard mask layer and portions of the sidewalls of the first via are defined by the patterned photoresist layer.

8. A semiconductor fabrication process, comprising:
forming a patterned hard mask layer overlying an interlevel dielectric layer (ILD) overlying a low-k dielectric layer;
forming spacers on sidewalls of the patterned hard mask layer, wherein the spacers define boundaries of a first opening and a third opening;
etching first and second vias in a low-k dielectric layer, wherein the first via is defined by the first opening and the second via is defined by a second opening;
removing the spacers to create a trench opening in the patterned hard mask layer; and
etching a trench defined by the patterned hard mask layer partially through the ILD.

9. The method of claim 8, further comprising forming a photoresist mask overlying the patterned hard mask layer, wherein the photoresist mask defines the second opening and a fourth opening, wherein the second opening is aligned with and smaller than the third opening and wherein the fourth opening is aligned with and wider than the first opening.

10. The method of claim 8, wherein etching the first and second vias includes etching entirely through the low-k dielectric layer and stopping on an etch stop layer (ESL) underlying the low-k dielectric layer.

11. The method of claim 8, wherein etching the first and second vias includes etching entirely through the low-k dielectric layer in addition to the ESL layer.

12. The method of claim 8 wherein etching the first and second vias includes partial etching of the low-k dielectric layer, in which the via low-k dielectric layer and ESL is fully opened during the subsequent trench etch.

13. The method of claim 8, wherein the ILD comprises an CVD inorganic low-k dielectric layer overlying a CVD low-k etch stop layer (ESL).

14. The method of claim 8, wherein etching the trench comprises forming photoresist plugs in lower portions of the first and second vias prior to etching the trench.

15. The method of claim 14, wherein etching the trench further includes removing the photoresist plugs and clearing the ESL.

16. The method of claim 8, wherein the first via is an isolated via.

17. A semiconductor fabrication process, comprising:
forming spacers on sidewalls of a patterned hard mask layer overlying an interlevel dielectric layer (ILD); and
defining a first opening by etching a first via having sidewalls in the ILD wherein at least a portion of the sidewalls are defined by the spacers.

18. The method of claim 17, wherein defining the first opening comprises defining a first opening in a region of an integrated circuit having isolated vias.

19. The method of claim 18, further comprising, after etching the first, removing the spacers and etching a first trench partially through the ILD, wherein the first trench is aligned with the first via.

20. The method of claim 19, further comprising, before etching the first trench, forming a photoresist plug in a lower portion of the first via.
